(19) United States
(12) Patent Application Publication
(10) Pub. No.: US 2006/0099786 A1
(43) Pub. Date: May 11, 2006

(54) Copper interconnect structure with modulated topography and method for forming the same

(75) Inventors: Su-Chen Fan, Ping-Jeng City (TW); Hsueh-Chung Chen, Yonghe City (TW)

Correspondence Address: DUANE MORRIS, LLP;IP DEPARTMENT, 30 SOUTH 17TH STREET, PHILADELPHIA, PA, 19103-4196, US

(73) Assignee: Taiwan Semiconductor Manufacturing Co.

(21) Appl. No.: 10/971,460

(22) Filed: Oct. 22, 2004

(51) Int. Cl. H01L 21/44

(52) U.S. Cl. 438/597

(57) ABSTRACT

A copper interconnect structure used in semiconductor devices includes surfaces having a surface roughness greater than 20 angstroms and which may be greater than 100 angstroms. The conformal surface of the copper interconnect structure confronts a surface roughened by ion bombardment. The copper interconnect structure is resistant to electromigration and stress migration failures.

### FIELD OF THE INVENTION

The present invention relates, most generally, to semiconductor devices and methods for their fabrication. More particularly, the present invention is directed to a structure and method used for copper interconnect technology.

### BACKGROUND

The use of copper as a conductive interconnect material is favored in semiconductor devices because of the high speed that copper provides. Copper interconnect leads are typically formed using damascene processing technology in which an opening is formed in a dielectric, copper is deposited within the opening, then a polishing/planarization process is used to remove copper from over the dielectric, leaving the copper inlaid within the opening. The copper interconnect lead is then in contact with the opposed sidewalls and bottom of the opening. In conventional openings formed using dry plasma etching operations, the sidewalls and bottom surface are typically very smooth, i.e., include a surface roughness less than 20 angstroms.

Although copper is favored as conductive interconnect material, safeguards must be taken to assure that phenomena such as electromigration and stress migration are avoided. Copper is prone to such phenomena. The smooth boundaries between the copper interconnect and the sidewalls and bottom of the opening in which the copper interconnect is disposed, provide a fast diffusion path that fosters electromigration and stress migration which degrades the copper interconnect reliability. Electromigration and stress migration phenomenon are both diffusion dominated phenomenon.

It would be desirable in the art of semiconductor device manufacturing to provide a copper interconnect technology in which the effects of stress migration and electromigration are considerably reduced or eliminated.

### SUMMARY OF THE INVENTION

To address these and other needs, and in view of its purposes, the present invention provides a method for forming a copper interconnect structure. The method includes providing a surface then using ion milling or other bombarding techniques to bombard the surface with energized species to roughen the surface. Copper is then deposited confronting the surface. The copper may be deposited conterminous with the surface or a barrier layer may be interposed between the surface and the copper material.

In another aspect, the invention provided is a method for forming a copper interconnect structure comprising providing a porous dielectric with a surface having a surface roughness within a range of 20 to 100 angstroms and conformally depositing copper confronting the surface.

In another aspect, the invention provides a semiconductor device comprising a copper interconnect structure having a copper surface with a surface roughness greater than 20 angstroms. The copper surface may form a conterminous boundary with a dielectric surface having substantially the same surface roughness, or the copper surface may be in confronting relationship with a further surface having substantially the same surface roughness.

In another aspect, the invention provides a semiconductor device comprising a copper interconnect structure confronting a surface having a surface roughness greater than 20 angstroms

### BRIEF DESCRIPTION OF THE DRAWING

The present invention is best understood from the following detailed description when read in conjunction of the accompanying drawing. It is emphasized that, according to common practice, the various features of the drawing are not necessarily to scale. On the contrary, the dimensions of the various features are arbitrarily expanded or reduced for clarity. Like numerals denote like features throughout the specification and drawing.

FIG. 1 shows a smooth surface as in the prior art;

FIG. 2 is a cross-sectional view showing a roughened surface according to the present invention;

FIG. 3 shows an opening formed in a dielectric and including roughened surfaces; and

FIG. 4 shows the structure of FIG. 3 after a copper interconnect has been inlaid within the opening shown in FIG. 3.

### DETAILED DESCRIPTION

According to one aspect, provided is a modulated structure for improving the reliability of copper interconnect. The modulated structure includes a roughened or corrugated topography for surfaces of the copper interconnect leads and contact structures. The roughened or corrugated topography reduces copper drift velocity, reduces electromigration and stress migration effects, and improves reliability by a factor of 2-3. The modulated topography, i.e., the roughened or corrugated surface of the copper interconnect lead, is formed by roughening the surface against which the copper interconnect lead will be formed then depositing copper conformally against the roughened surface. In another embodiment, the surface against which the copper interconnect lead will be formed may be a porous dielectric that includes a porous and roughened surface upon formation. MSQ (methylsilsesquioxane) is an example of such a porous dielectric.

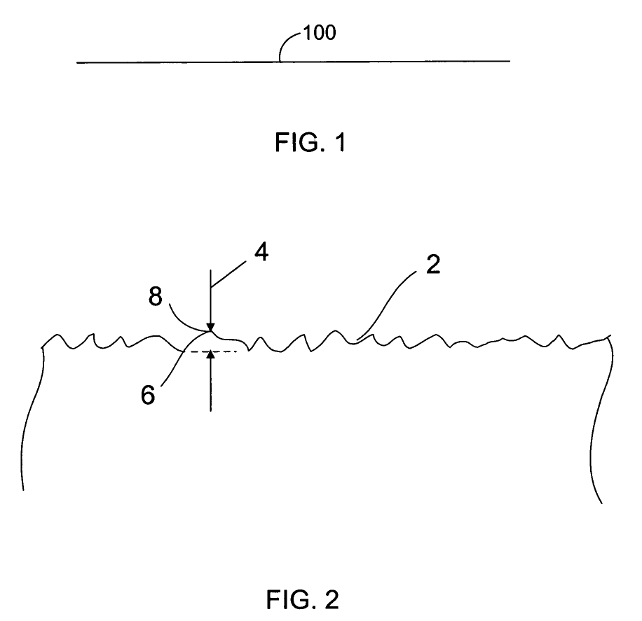

FIG. 1 shows a substantially smooth surface 100 as in the prior art. The substantially smooth surface includes a roughness of less than 20 angstroms. Roughness is measured as the difference between highest and deepest surface features. FIG. 2 shows a roughened surface such as produced by the invention. Roughened surface 2 includes a roughness greater than 20 angstroms in one exemplary embodiment and may include a roughness greater than 100 angstroms in other exemplary embodiments. The roughness values represent distance 4 between highest point 8 and deepest point 6 of roughened surface 2. Roughened surface 2 may be a dielectric, a cap layer formed over a dielectric or a conductive material.

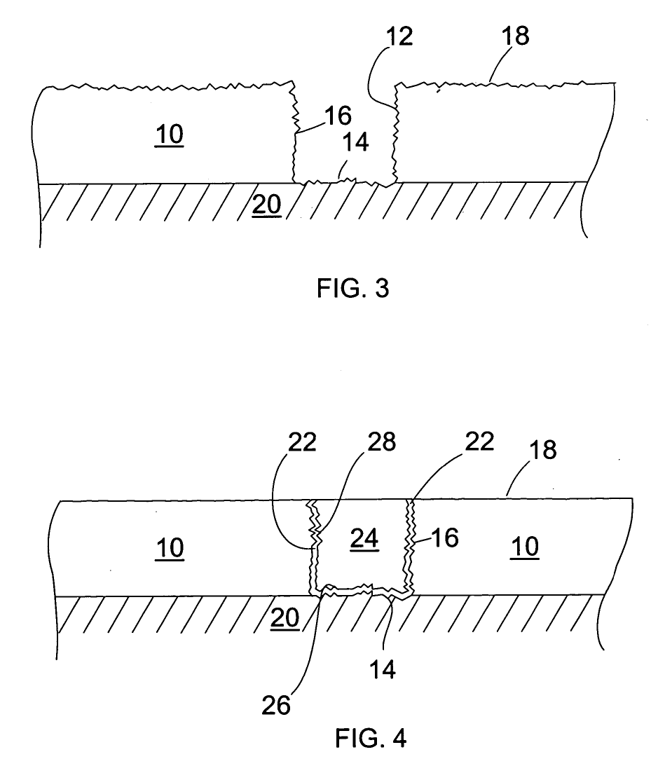

FIG. 3 is a cross-sectional view showing an exemplary structure including roughened surfaces provided by the invention and shows an opening formed in a dielectric. A copper interconnect material such as a lead or contact or via structure may be received in the opening. Dielectric 10 may be various dielectric materials such as silicon dioxide, silicon nitride, silicon oxy-nitride and other suitable materials. Dielectric 10 may be a low-k material having a dielectric constant, k, less than that of silicon dioxide, about 3.9. Dielectric 10 may be chosen to be a porous material and it may be both a porous material and a low-k material. The low-k dielectric material may be a CVD low-k material, i.e., one formed by chemical vapor deposition, or a spin-on low-k materials. In one exemplary embodiment, porous MSQ (methylsilsesquioxane) may be used. The porous and low-k dielectric materials are advantageously chosen so that subsequent ion bombardment/ion milling operations can advantageously and efficiently roughen the surface.

FIG. 3 includes opening 12 formed within dielectric 10 and exposing subjacent conductive material 20. Opening 12 includes bottom 14 which is a surface of conductive material 20, and sidewalls 16. Dielectric 10 also includes top surface 18. Opening 12 is formed using conventional plasma etching techniques and upon formation, bottom 14 and sidewall 16 are substantially smooth. In other words, they include a surface roughness less than 20 angstroms when formed. Top surface 18 may also be substantially smooth prior to the roughening operation aspect of the invention. Opening 12 may be a trench opening, a via opening, a contact opening or various other openings. In another exemplary embodiment, opening 12 may be a dual damascene trench opening. In yet another exemplary embodiment, opening 12 may not extend down to conductive material 20 but, rather, may terminate within dielectric 10. In another exemplary embodiment, a SiC, SiN or other cap layer may be formed.

Once the surface or surfaces that will confront the copper interconnect are initially formed as relatively smooth surfaces (not shown), they are then exposed to a roughening treatment according to the invention and roughened surfaces such as shown in FIG. 3 are produced. Ion bombardment or ion milling may be used to roughen the surface. Other etching techniques that use energized species for physical etching may also be used. Highly energized species such as Ar⁺, Xe⁺, Ta⁺, Cu⁺ or other suitable high energy ions may be used and accelerated towards the surface using various conventional tools. The power and energy level of the ion bombardment/ion milling operation is chosen to cause the excited, energized species roughen the surface and produce a surface roughness greater than 20 angstroms and advantageously greater than 100 angstroms. In an exemplary embodiment, the ion bombardment operation may include Ta⁺ as the energized species and process conditions may be in the range of DC power 1000˜9000 W and RF power 300˜9000 W. The roughening process of the present invention roughens the surface of sidewalls 16 and top surface 18 of dielectric 10 as well as bottom 14 of opening 12 which is a surface of conductive material 20. Roughened surfaces sidewalls 16, top surface 18 and bottom 14 may take on the appearance of the surface shown in further detail in FIG. 2, or they may take on a corrugated appearance. According to an exemplary embodiment in which a barrier layer is formed prior to the copper interconnect, the ion milling operation may be performed in-situ and preceding the barrier layer deposition process. In one exemplary embodiment, the barrier layer deposition characteristics may be adjusted to include a high power and energy at the initial stages of the deposition process so as to bombard and roughen or corrugate the surface. In an another exemplary embodiment, the roughening step may be an initiation step in the optional barrier layer deposition process. According to an exemplary embodiment in which no barrier layer is used and the copper is formed directly on roughened surfaces, the ion milling operation may be performed in-situ and preceding the copper deposition process. The copper deposition characteristics may be adjusted to include a high power and energy at the initial stages of the deposition process so as to bombard and roughen or corrugate the surface. In an another exemplary embodiment, the roughening step may be an initiation step in the copper deposition process.

FIG. 4 shows a copper interconnect structure formed within opening 12 shown in FIG. 3. The copper interconnect structure includes copper 24 and barrier layer 22 filling opening 12 of FIG. 3. Various barrier materials are known in the art and various suitable barrier layers and methods for forming the same may be used. Barrier layer 22 is a conformal film and maintains the surface roughness of the roughened surfaces, e.g., 14 and 16, upon which it is formed. Copper 24 is then formed on barrier layer 22 using various conventional sputtering, evaporation, electroplating or electroless-plating processes, in the illustrated embodiment. The copper deposition characteristics are chosen so that the copper film is a substantially conformal film and will therefore include a surface having the same roughness or corrugation as any surface that it confronts. In one exemplary embodiment (not shown) where the optional barrier layer is not used, copper 24 and roughened surfaces 14 and 16 have a conterminous relationship and therefore the same surface roughness. In the exemplary embodiment illustrated in FIG. 4, barrier layer 22 is interposed between copper 24 and roughened surfaces 14 and 16, but since barrier layer 22 is a conformal film that substantially maintains the roughness of roughened surfaces 14 and 16, copper 24 includes surfaces 26 and 28 that confront surfaces 14 and 16 respectively and include substantially the same surface roughness. FIG. 4 also shows the structure after a polishing operation has been used to remove copper material from over top surface 18 which may undergo smoothing in the polishing operation. In either embodiment, the copper interconnect structure includes copper 24 formed to include surfaces that confront bottom surface 14 and sidewalls 16, each of which includes the roughened/corrugated surface of the invention, i.e., a surface with a surface roughness greater than at least 20 angstroms. As such, conformal copper surfaces 26 and 28 also include a surface roughness of greater than 20 angstroms, and greater than 100 angstroms in an advantageous embodiment. FIG. 4 is an exemplary embodiment shown in cross-section and may illustrate a contact, via or damascene interconnect structure.

In another embodiment, the surface against which the copper interconnect lead will be formed may be a porous dielectric that includes a pore size that provides a roughened surface with a surface roughness in the 20 to 100 angstroms range. MSQ (methylsilsesquioxane) may include a pore size in the 10 to 50 angstrom range and may include such a surface roughness such as roughened surface 2 illustrated in FIG. 2. In this exemplary embodiment, the bombardment process may additionally be used or it may not be needed.

The preceding merely illustrates the principles of the invention. It will thus be appreciated that those skilled in the art will be able to devise various arrangements which, although not explicitly described or shown herein, embody the principles of the invention and are included within its spirit and scope. Furthermore, all examples and conditional language recited herein are principally intended expressly to be only for pedagogical purposes and to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What is claimed is:

1. A method for forming a copper interconnect structure comprising:
providing a surface;
bombarding with an energized species to roughen said surface; and
conformally depositing copper confronting said surface.

2. The method as in claim 1, wherein said conformally depositing copper produces a copper surface with a surface roughness greater than 20 angstroms.

3. The method as in claim 1, wherein said bombarding comprises ion milling and includes conditions that roughen said surface to a surface roughness greater than 20 angstroms.

4. The method as in claim 1, further comprising forming a barrier layer between said surface and said copper wherein said copper surface and said further surface each include a surface roughness greater than 20 angstroms.

5. The method as in claim 4, wherein said bombarding comprises an initiation step performed in-situ with and preceding said forming a barrier layer.

6. The method as in claim 1, wherein said surface comprises a dielectric surface.

7. The method as in claim 6, wherein said surface comprises at least one of a low-k dielectric and a porous dielectric.

8. The method as in claim 1, wherein said copper forms a conterminous boundary with said surface.

9. The method as in claim 1, wherein said bombarding produces a surface roughness greater than 20 angstroms on said surface.

10. The method as in claim 1, wherein said surface comprises sidewalls and a bottom of an opening formed in a dielectric.

11. The method as in claim 1, wherein said providing a surface comprises forming a dielectric and forming a damascene opening therein, wherein said surface comprises a bottom and sidewalls of said damascene opening.

12. The method as in claim 11, wherein said bottom comprises a conductive portion.

13. The method as in claim 1, wherein said energized species comprise at least one of Ar⁺, Xe⁺, Ta⁺ and Cu⁺.

14. The method as in claim 1, wherein said bombarding comprises an initiation step performed as part of said conformally depositing copper.

15. A method for forming a copper interconnect structure comprising providing a porous dielectric with a surface having a surface roughness within a range of 20 to 100 angstroms and conformally depositing copper confronting said surface.

16. A semiconductor device comprising a copper interconnect structure having a copper surface with a surface roughness greater than 20 angstroms.

17. The semiconductor device as in claim 16, wherein said copper surface forms a conterminous boundary with a dielectric surface having substantially the same surface roughness.

18. The semiconductor device as in claim 16, wherein said copper surface is in confronting relationship with a further surface having substantially the same surface roughness.

19. The semiconductor device as in claim 18, further comprising a barrier layer interposed between said copper surface and said further surface.

20. The semiconductor device as in claim 18, wherein said further surface comprises a surface of a low-k dielectric.

21. The semiconductor device as in claim 18, wherein said further surface comprises a surface of a porous dielectric.

22. The semiconductor device as in claim 18, wherein said further surface comprises bottom and sides of an opening formed in a dielectric.

23. The semiconductor device as in claim 22, wherein said opening comprises a dual damascene opening and said bottom comprises a conductive material.

24. The semiconductor device as in claim 18, wherein said copper surface and said further surface each include a surface roughness greater than 100 angstroms.

25. A semiconductor device comprising a copper interconnect structure having a surface conterminous with a surface having a surface roughness greater than 20 angstroms.

26. The semiconductor device as in claim 25, wherein a surface of said copper interconnect structure and said surface each include a surface roughness greater than 100 angstroms.
